(19) United States
(12) Patent Application Publication
(10) Pub. No.: US 2012/0176121 A1
(43) Pub. Date: Jul. 12, 2012

(54) CURRENT PASSAGE INDICATOR

(75) Inventors: Graham Earp, Cheshire (GB); Richard Ash, Cheshire (GB)

(73) Assignee: EA TECHNOLOGY LIMITED, Cheshire (GB)

(21) Appl. No.: 13/382,090

(22) PCT Filed: Jul. 5, 2010
(86) PCT No.: PCT/GB10/51104

§ 371 Date: Mar. 27, 2012

(30) Foreign Application Priority Data
Jul. 3, 2009 (GB) 0911574.2

(51) Int. Cl. G01R 1/20

(52) U.S. Cl. 324/126

(57) ABSTRACT

A fault current passage indicator (100) is fitted around the earth conductor (11) of a pole (10) supporting a section of an overhead electricity distribution network. This is achieved by means of a clip (110) adapted to provide a loop of ferromagnetic material enclosing the earth conductor (11). The indicator 100 is operable to detect transient earth currents flowing in the earth conductor (11). This is achieved by the provision of a sensor coil (101) is fitted around the clip (110) such that a portion of the clip (110) passes through the core of the sensor coil (101). Detected incidents of transient earth currents are recorded by the indicator (100) and data relating thereto can be retrieved by use of a suitable reader device (200). The indicator (100) is further adapted to scavenge power for operation from either transient earth currents or the reader device (200).

The present invention relates to a current passage indictor and in particular to a current passage indicator suitable for detecting and indicating the presence of transient earth currents on earth conductors of earthed supports used on overhead electricity transmission and distribution lines.

High voltage (HV) insulation faults on earthed supporting structures (including wood, concrete and composite poles) on the high voltage overhead electricity distribution network will frequently lead to supply interruptions when the line trips due to the passage of excess earth current. Most line trip faults are likely to occur on structures fitted with an earth conductor as this provides a route for the fault current required to trip the line. Un-earthed insulating support structures are unlikely to give rise to a trip in the first place due to their insulating properties.

The supply interruption may result either from the sensitive earth fault (SEF) protection system tripping the line (typically set to an earth current threshold in the range 10-20 A) or from the excess current protection system threshold being exceeded (maybe 10's to several hundred amperes). Either way, a significant transient earth current in the range 10-1000 A may be expected momentarily down the HV earth conductor on the offending support. The HV fault may typically be attributed to a cracked insulator, damaged bushing or arcing horn, faulty surge arrester, or internal breakdown within a transformer, flashover or bird strike for example.

Following a trip, the line may be re-energised; either manually, or automatically via an auto-recloser. Unless the fault has cleared, the likelihood is that it will trip again almost immediately. If the line remains energised, there is still a good chance that it will trip again in the future because the original fault will still be present.

Such faults can be troublesome to locate, particularly if the line will not remain energised and continues to trip each time an attempt is made to restore supplies. Traditionally, methods for locating such faults include sectionalising (i.e. successive isolation of parts of the network), or the fitting of fault current passage indicators. Both methods are time consuming and require a lot of travelling around the network.

Known fault current passage indicators are fitted towards the top of a support structure. Therefore the fitting of an indicator of the known type requires climbing the support structure and making a permanent attachment. Such attachment is a skilled job requiring many safety precautions to be taken. It may also be necessary to de-energise the line in order to make it safe to fit the indicator in close proximity to the power conductors. Even with judicious placement of the devices it can take several attempts to narrow down the fault location to a small area using this technique. Whilst some types of indicator can derive their power from the line (usually from the electric field produced by the live conductors), most are powered by internal batteries to reduce cost. Leaving the indicator installed permanently is both expensive (because many indicators are needed) and of limited usefulness because of the short life of batteries. It can be difficult to determine whether or not an indicator has stopped working due to a flat battery. It is both time consuming and costly to have to periodically check and/or replace the batteries in all the indicators across the entire network.

It is therefore an object of the present invention to provide a transient earth current passage indicator that at least partially overcomes or alleviates the above problems.

According to a first aspect of the preset invention there is provided a current passage indicator comprising: a clip adapted to retain the indicator in position adjacent to a conductor; a sensor coil adapted to be energised by the passage of current through the conductor; a processor operable in response to the sensor coil being energised to increment a counter stored in non-volatile memory; and an interface operable to enable data to be transferred from the non-volatile memory to external circuitry.

In this manner, the indicator may be powered by the passage of a fault current rather than requiring an internal battery or mounting physically close enough to the live conductors in order to extract power from their electric field. As such, it can be fitted to an earth conductor near the base of a support without the need for special precautions in doing so, and can remain in service indefinitely without requiring battery replacement.

The conductor may be an earth conductor. In particular the conductor may be an earth conductor provided on, fitted to or adjacent to a support structure for an overhead electrical conductor or conductors. One example might be the conductors used on an overhead line electricity distribution network. The support structure may be a wooden, composite or concrete pole or similar.

Typically the support structure is an insulating support structure, however in suitable circumstances the indicator may be fitted to a conducting support, for example a steel pole, gantry support, tower leg or similar. Additionally or alternatively, the indicator may be fitted to an earth conductor of a conducting support. One example might be fitting the indicator to a bond jumper connecting a metal railway power line gantry support mounted on a concrete (or similar) base to earth.

The clip may be provided with fixing means for attaching the clip to the support structure. The fixing means may comprise one or more bolts, screws, nails or similar. The clip is preferably formed from a material having a high magnetic susceptibility. The clip is preferably adapted such that it provides a complete loop surrounding the conductor. This may be achieved by a two part construction wherein a first portion is adapted to fit between the conductor and the support structure and a second portion carries the sensor coil. The two portions may be connected by any suitable means. In particular the two portions may be fixed together by a suitable snap fitting arrangement, one or more bolts, screws nails or similar. The two portions may be fixed together by the fixing means for attaching the clip to the support structure.

The sensor coil, processor and indicator may be encapsulated in a suitable housing. The clip or either or both portions of the clip may be encapsulated in a housing. The clip or the portion of the clip carrying the sensor coil may be encapsulated either wholly or partially in the same housing as the sensor coil, processor and indicator. The portion of the clip adapted to fit between the conductor and the support structure may be encapsulated in a separate housing. The encapsulation of the components of the indicator provides protection against the elements.

The processor may be operable to draw power directly from the energised sensor coil or from a power transfer coil. Alternatively, an energy scavenging means may be provided between the processor and the sensor coil and/or the power transfer coil, the energy scavenging means adapted to draw power from the energised coil and feed said power to the processor. The energy scavenging means may be operable to feed power to an energy storage means. The energy storage means may store a small amount of energy during periods when the processor is inactive so that this energy can be used to power the processor or other features of the indicator when required. The energy storage means may comprise any suitable storage means examples including but not limited to a low-loss rechargeable battery or a low-leakage capacitor.

In addition to incrementing the counter in response to sensor coil energisation, the processor may be operable in some embodiments to store an associated time stamp indicating the time of sensor coil energisation. The processor may be operable to cause the interface to transfer data on each occasion that the sensor coil is energised. Alternatively, the processor may be operable to cause the interface to transfer data only on selected occasions or only in response to further occurrences,

The interface may take any suitable form allowing for the transfer of data. The interface may be suitable for transferring data only or may be further adapted to provide power to the indicator. If the interface is adapted to provide data transfer only, power may be provided to the indicator by an alternative means. In particular power may be provided from a non-contact source such as a local electro-magnetic field. In such cases, the processor may be operable to distinguish between the sensor coil being energised by a fault current and another power source.

The interface may be adapted to provide one way data transfer from the indicator to external circuitry or two way data transfer between the indicator and external circuitry. The interface may be adapted to provide wireless or wired data transfer. If the interface provides wireless one way transfer, the interface may comprise an infra red or optical LED or an RF transmitter. If the interface provides wireless two way transfer, the interface may comprise an infra red, optical LED or RF transceiver. In suitable cases, the interface may be adapted to include a length of optic fibre in order to simplify making the infra red or optical connection between the indicator and the external circuitry. The external circuitry may be a dedicated reader device or any other suitable device in communication with the indicator. If the external circuitry is a dedicated reader device it is typically provided locally or transported to the vicinity of the indicator. Additionally or alternatively, in cases wherein the indicator is suitably equipped, the external circuitry may be a local or remote data collector or a device in communication with the indicator via a long range network such as a cellular telephone network.

In some embodiments, the interface may be adapted to receive power in addition to allowing data transfer.

According to a second aspect of the present invention there is provided a reader device for reading data from an indicator according to the first aspect of the present invention, the reader device comprising: data transfer means adapted to connect with the interface of the indicator and thereby enable the transfer of data from the indicator to the reader device; and power transfer means adapted to transfer power to the indicator from the reader device.

The reader device of the second aspect of the invention may incorporate any or all features of the first aspect of the present invention or features corresponding to features of the first aspect of the present invention as desired or as appropriate.

The data transfer means of the reader device preferably corresponds to the interface provided on the indicator. As such, the data transfer device may be an infrared transceiver, an optical transceiver, an RF transceiver or a data cable as required.

The power transfer means may be a power cable or may be a non-contact power transfer means operable to energise the sensor coil and thereby transfer power to the processor. The processor may be operable to distinguish between the sensor coil being energised by a fault current and the power transfer means. The power transfer means may energise the sensor coil with a particular pattern of energisation or the power transfer means may energise the sensor coil in association with the provision of an associated signal via the data transfer means. This can help aid in distinguishing between a fault current and energisation by the power transfer means via the sensor coil. In suitable embodiments of the indicator and the reader device, the power transfer means may be operable to transfer power via a second power transfer coil in the interface, either instead of, or in addition to, transfer of power via the sensor coil.

The reader device may further comprise a display and user input means. The reader device may be provided with a battery to supply power to the power transfer means. In some embodiments the reader may comprise an RF transmitter operable to communicate regular updates on the number of fault events detected by the indicator. In particular the RF transmitter may be a transmitter or transceiver operable to transfer data to a remote location, data collector or over a cellular telephone network. This can allow data as to fault current events to be directly transmitted to a central control by an engineer in the field. It can also allow information from a central control centre to be received on the reader by an engineer in the field. For example, such information might usefully include work schedules, geographical information and details of the power line being tested. The reader device may also comprise a satellite positioning receiver such as a GPS (Global Positioning Service) receiver. This allows the reader device's geographical position to be determined and recorded at any time.

In some embodiments, the reader device may be adapted to be fixed to a support structure alongside the indicator. In such embodiments, the reader may be powered from an internal battery or from the monitored transmission line or from an alternative energy source. The alternative energy source may comprise, for example, a photo-voltaic cell, a wind generator or similar. Additionally, in such embodiments, the reader preferably comprises an RF transmitter operable to communicate regular updates to external circuitry. These updates may relate to the number of fault events detected by the indicator, as described above. This can allow temporary or permanent (as desired) remote monitoring of an overhead electricity distribution network. This may be necessary or desirable if a large number of faults are occurring in particular parts of the network or if it is proving particularly difficult to isolate a fault.

According to a third aspect of the present invention there is provided a method of monitoring an overhead electricity distribution network comprising the steps of fitting one or more indicators according to the first aspect of the present invention to one or more selected earthed support structures of the network; and checking the one or more selected earthed support structures for faults by use of one or more reader devices according to the second aspect of the present invention.

The method of the third aspect of the present invention may incorporate any or all features of the first or second aspects of the present invention as are desired or as are appropriate.

The method may be carried out by use of one or more portable reader devices transported to one or more indicators. Additionally or alternatively the method may be carried out by fixing dedicated reader devices adjacent to the indicator devices on one or more selected support structures of the network. In such implementations, the reader preferably comprises an RF transmitter or transceiver operable to communicate regular updates on the number of fault events detected by the indicator. This can allow temporary or permanent (as desired) remote monitoring of an overhead electricity distribution network. This may be necessary or desirable if a large number of faults are occurring in particular parts of the network or if it is proving particularly difficult to isolate a fault.

In order that the invention may be more clearly understood, one embodiment is described in more detail below, by way of example only, and with reference to the accompanying drawings:

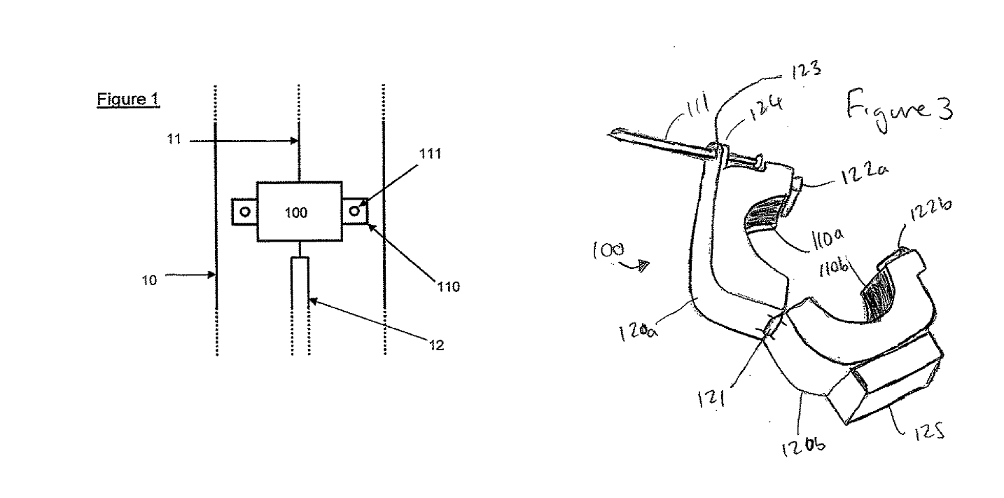

FIG. 1 shows a fault current indicator according to the present invention fixed to the earth conductor of a pole of an overhead electricity distribution network;

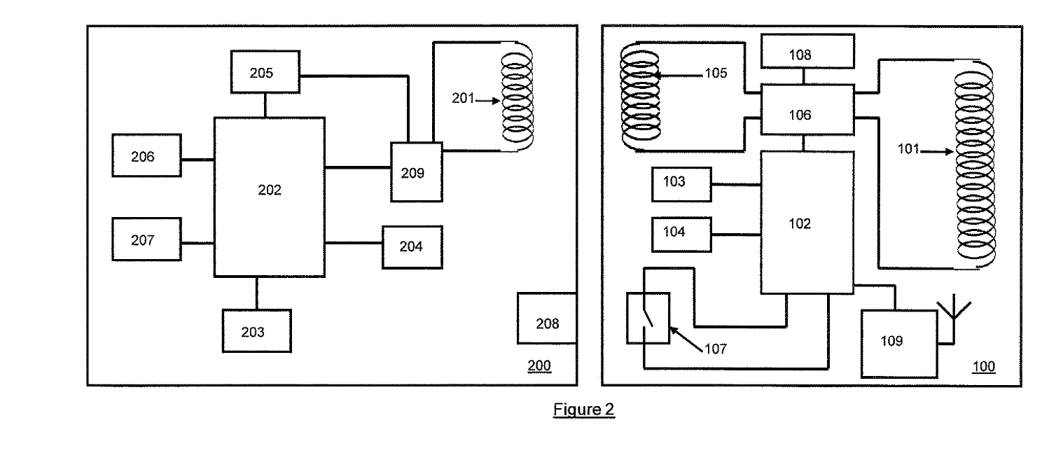

FIG. 2 is a schematic block diagram of the indicator of FIG. 1 and an associated reader device; and

FIG. 3 shows one possible embodiment of an indicator according to the present invention

Referring now to FIG. 1, a fault current passage indicator 100 is provided on a support structure, in the example shown a pole 10, of an overhead electricity distribution network. The indicator 100 is fitted around the earth conductor 11 of the pole 10 by means of a clip 110 of ferromagnetic material. The clip 110 is adapted to provide a loop enclosing the earth conductor 11 and is fixed to the pole 10 by bolts 111. The indictor 100 is fitted above a protective guard 12 for the bottom of the earth conductor 11.

The indicator 100 is operable to detect transient earth currents flowing in the earth conductor 11. Detected incidents of transient earth currents are recorded by the indicator 100 and data relating thereto can be retrieved by use of a suitable reader device 200. The indicator 100 is further adapted to scavenge power for operation from either transient earth currents, earth leakage currents, or the reader device 200.

One such indicator device 100 may be fitted to the earth conductor 11 of each earthed pole 10 of an overhead electricity distribution network. This can be done either during routine line inspection or during fault location exercises. An inspector may then travel to each of the poles 11 with indicators 100 fitted at a later time to determine which indicators 100 had detected fault current events. This can identify a pole 10 where the line requires maintenance. Since the indicator 10 can detect relatively small fault current events, it may be possible to identify poles 10 where the lines require maintenance before a major fault occurs.

Turning now to FIG. 2, a schematic block diagram of the indicator device 100 and the reader device 200 is shown. The indicator comprises a sensor coil 101, a processor 102, non-volatile memory 103 and an interface 104.

The sensor coil 101 is fitted around the clip 110 such that a portion of the clip 110 passes through the core of the sensor coil 101. Since the clip 110 is comprised of material having a high magnetic susceptibility, a current flowing in conductor 11 will generate a magnetic flux in the clip 110, which will in turn induce a current in the sensor coil 101. As such, a fault current in the conductor 11 energises the sensor coil 101. The processor 102 is operable to draw power from the energised sensor coil 101 via a power rectification and conditioning unit 106. When drawing power from sensor coil 101 the processor 102 is operable to increment a counter stored in non-volatile memory 103, The interface 104 is connected to the processor 102 and is operable to transfer data from the non-volatile memory 103 to external circuitry. In a preferred embodiment, the interface 104 comprises an infra red LED. In alternative embodiments, the interface 104 may operate using optical data transfer, RF data transfer, or even wired data transfer.

The reader 200 comprises a data transfer means 204, a processor 202, a data storage means 203 a power transfer means 201. The data transfer means 204 corresponds to the interface 104 and is operable to receive data transmitted by the interface 104. Accordingly, in a preferred embodiment, the data transfer means 204 comprises an infrared receiver.

In order to receive data from the indicator 100 the reader device comprises a power transfer means 201 operable under the control of processor 202 to supply power to the indicator 100. The power transfer can take place via any suitable wired or wireless link. In a preferred embodiment shown in FIG. 2, the power transfer means is a dedicated transmitter coil 201 operable to generate an electro-magnetic field to energise a corresponding power transfer coil 105. In such embodiments, in order that the processor 102 can distinguish between the sensor coil 101 being energised by a fault current on conductor 11 or the power transfer coil 105 being energised via the power transfer coil 201 a small fixed magnet 208 is incorporated in to the reader 200. The magnet 208 operates a reed switch 107 in the indicator device 100 when the reader 200 is in close proximity thereto. The power transfer coil 201 is connected to a suitable power source 205, such as an internal battery, via a power conditioning unit 209.

Whilst in the embodiment shown in FIG. 2, a dedicated power transfer coil 105 is provided, the skilled man will appreciate that in alternative embodiments it may be possible for the sensor coil 101 to be utilised as a power transfer coil in addition to detecting transient current events. Furthermore, as is shown in FIG. 2, the indicator may optionally comprise an energy storage means 108 operable to store electrical energy scavenged from energisation of the sensor coil 101 or the power transfer coil 105. The energy storage may be controlled by the power conditioning unit 106. Additionally, the indicator may include an RF transmitter or transceiver 109 that on occasions can be powered from the energy storage unit 108 and can be used to communicate regular updates on the number of fault events detected by the indicator or other data to a remote location, data collector or over a cellular telephone network.

The data received from the indicator may be stored in the data storage means 203. Additionally or alternatively, this data may be output to a display unit 206 provided on the reader device 200. This can allow an engineer to directly know how many fault current events have taken place at a particular pole 10. The reader device 200 is also provided with user input means 207, to allow a user to control its operation.

In some embodiments, the count held in the memory 103 is reset after this data has been transferred to the reader 200. The time and date details of this reset event may be recorded in the memory 103.

In an alternative embodiment, the reader may further comprise an RF transmitter operable to transmit data from the reader device 200 to a remote location. This can allow an engineer in the field to provide data updates to a central network control unit. If persistent faults are experienced or if a particular fault is difficult to isolate one or more such transmitter equipped readers 200 can be fitted to poles 10 as dedicated readers for particular indicators 100. This enables remote monitoring of faults on the network.

Turning now to FIG. 3, one possible implementation of a fault current passage indicator 100 is illustrated as an example. The indicator 100 of FIG. 3 comprises a first clip section 110a within a first protective housing section 120a and a second clip section 110b within a second protective housing section 120b. The two housing sections 120a, 120b are connected by a hinge 121 and may be releasably connected via fixing means 122a, 122b, typically, a cooperating snap fitting arrangement. The first housing section is adapted to be fixed to a pole 10 via a nail, screw or bolt 111 inserted through a bore 123 provided in a projecting tab 124.

The sensor coil 101 is provided around second clip section 110b within housing section 120b. The sensor coil 101 is connected to the processor 102 and other components such as non-volatile memory 103, interface 104, power transfer coil 105, power rectification unit 106 and reed switch 107. The processor and other components are mounted within auxiliary protective housing section 125, which is fixed to the second housing section 120b.

In order to fit the indicator 100 a user may release the fixing means 122a, 122b and insert the first housing section 121a between an earth conductor 11 and a pole 10. The user can then attach the first housing section 121a to the pole using a suitable nail or screw 111 in combination with tab 124 and bore 123. The user can subsequently close the clip using attachment means 122a, 122b. The clip sections 110a and 110b are thus connected together, facilitating the operation of the indicator in the manner described previously.

It is of course to be understood that the present invention is not to be restricted to the details of the above embodiment which is described by way of example only.

1-38. (canceled)

39. A current passage indicator suitable for detecting and indicating the presence of transient earth currents on earth conductors provided on, fitted to or adjacent to a support structure for an overhead electrical conductor, the indicator comprising: a clip adapted to retain the indicator in position adjacent to a conductor; a sensor coil adapted to be energised by the passage of current through the conductor; a processor operable in response to the sensor coil being energised to draw power directly from the energised sensor coil to thereby enable the processor to increment a counter stored in non-volatile memory; an interface operable to enable data to be transferred from the non-volatile memory to external circuitry; and power transfer means adapted to transfer power to the indicator to enable said data transfer.

40. A current passage indicator as claimed in claim 39 wherein the clip is formed from a material having a high magnetic susceptibility and wherein the clip is adapted such that it provides a complete loop surrounding the conductor.

41. A current passage indicator as claimed in claim 40 wherein the clip has a two part construction wherein a first portion is adapted to fit between the conductor and the support structure and a second portion carries the sensor coil.

42. A current passage indicator as claimed in claim 41 wherein the clip is encapsulated in a housing or both portions of the clip are encapsulated in housings and wherein the sensor coil, processor and indicator are encapsulated in a suitable housing.

43. A current passage indicator as claimed in claim 39 wherein the power transfer means comprise a power transfer coil adapted to draw power from a local electromagnetic field.

44. A current passage indicator as claimed in claim 43 wherein an energy scavenging means is provided between the processor and the sensor coil and/or the power transfer coil, the energy scavenging means adapted to draw power from the energised coil and feed said power to the processor.

45. A current passage indicator as claimed in claim 44 wherein the energy scavenging means is operable to feed power to an energy storage means.

46. A current passage indicator as claimed in claim 39 wherein the processor is operable to store an associated time stamp indicating the time of coil energisation in addition to incrementing the counter in response to coil energisation.

47. A current passage indicator as claimed in claim 44 wherein the processor is operable to distinguish between the sensor coil being energised by a fault current and another power source.

48. A current passage indicator as claimed in claim 39 wherein the interface is adapted to provide two way data transfer between the indicator and external circuitry.

49. A current passage indicator as claimed in claim 48 wherein the interface is a wired connection or is a suitable infrared, optical or RF transceiver.

50. A reader device for reading data from an indicator according to claim 1, the reader device comprising: data transfer means adapted to connect with the interface of the indicator and thereby enable the transfer of data from the indicator to the reader device; and power transfer means adapted to transfer power to the indicator from the reader device to enable said data transfer.

51. A reader device as claimed in claim 50 wherein the data transfer device is any one of an infrared transceiver, an optical transceiver, an RF transceiver or a data cable as required.

52. A reader device as claimed in claim 50 wherein the power transfer means is a non-contact power transfer means.

53. A reader device as claimed in claim 52 wherein the power transfer means energises the coil with a particular pattern of energisation.

54. A reader device as claimed in claim 52 wherein the power transfer means energises the coil in association with the provision of an associated signal via the data transfer means.

55. A reader device as claimed in claim 50 wherein the reader device may also comprises a satellite positioning receiver

56. A reader device as claimed in claim 50 wherein the reader device comprises an RF transmitter operable to communicate regular updates to external circuitry.

57. A reader device as claimed in claim 50 wherein the reader device is adapted to be fixed to a support structure alongside the indicator.

58. A reader device as claimed in claim 50 wherein the reader is powered from an internal battery or from the monitored transmission line, a photo voltaic cell or a wind generator.

59. A method of monitoring an overhead electricity distribution network comprising the steps of fitting one or more indicators according to any one of claim 1 to one or more selected earthed support structures of the network; and checking the one or more selected earthed support structures for faults by use of one or more reader devices according to claim 12.

60. A method as claimed in claim 59 wherein the method is carried out by use of one or more portable reader devices transported to one or more indicators and/or wherein the method is carried out by fixing dedicated reader devices adjacent to the indicator devices on one or more selected support structures of the network.
